(19) United States
(12) Patent Application Publication
(10) Pub. No.: US 2013/0028450 A1
(43) Pub. Date: Jan. 31, 2013

(54) LID, FABRICATING METHOD THEREOF, AND MEMS PACKAGE MADE THEREBY

(71) Applicants: STMicroelectronics S.r.l., Agrate Brianza (IT); Unimicron Technology Corp., Taoyuan (TW)

(72) Inventors: Mario Cortese, Milan (IT); Mark A. Azzopardi, Ciuoja (MT); Shih-Ping Hsu, Lu-Zhu Township (TW); Kun-Chen Tsai, Ping-Tung City (TW); Ivan Micallef, Birkirkara (MT)

(73) Assignees: UNIMICRON TECHNOLOGY CORP., Taoyuan (TW); STMICROELECTRONICS S.R.L., Agrate Brianza (IT)

(21) Appl. No.: 13/646,249

(22) Filed: Oct. 5, 2012

Related U.S. Application Data
(63) Continuation of application No. 13/475,512, filed on May 18, 2012.
Application No. 13/475,512 is a continuation-in-part of application No. PCT/IT2009/000527, filed on Nov. 20, 2009.

(51) Int. Cl. H04R 1/00; B32B 38/08; B32B 3/02; B32B 38/04; H01L 27/20; H05K 1/11

(52) U.S. Cl. 381/174; 257/415; 174/266; 428/166; 156/252; 156/150; 257/E27.006

(57) ABSTRACT

A lid for a MEMS device and the relative manufacturing method. The lid includes: a first board with opposite first and second surfaces having first and second metal layers disposed thereon, respectively, wherein a through cavity extends through the first board and the first and second metal layers; a second board with opposite third and fourth surfaces; an adhesive layer sandwiched between the second surface of the first board and the third surface of the second board to couple the first and second boards together such that the through cavity is closed by the second board, thereby forming a recess; and a first conductor layer coating the bottom and the side surfaces of the recess.

### BACKGROUND

1. Technical Field

The present disclosure relates to a lid, the fabricating method thereof, and a MEMS (micro-electro-mechanical system) package made thereby, and more particularly, to a lid with metalized recess, the fabricating method thereof, and a MEMS package made thereby to have an enhanced shielding effect upon the MEMS.

2. Description of the Prior Art

MEMS devices, such as microphones, are in wide use in mobile communication devices, audio devices, etc. To achieve miniaturization, microphones for use as hearing aid units, typically known as condenser microphones, are downsized. However, the transducer therein is fragile and susceptible to physical damage. Furthermore, since signal transmission may be disturbed by the environment, the transducer should be protected from light and electromagnetic interferences. Moreover, favorable acoustic pressure is desired for the transducer to function properly, as far as prevention of light and electromagnetic interference is concerned. Please refer to FIG. 1 for condenser microphones in wide use.

Referring to FIG. 1, a conventional condenser microphone comprises: a first substrate 10, a conductive plate 11 coupled to the first substrate 10 by means of a conductive adhesive layer 13, and a second substrate 12 coupled to the conductive plate 11 by means of another conductive adhesive layer 13′. The first substrate 10 comprises a mold plate 100 and a backboard 101, and so does the second substrate 12. An auditory aperture 102 is formed in the first substrate 10. A semiconductor chip 14 is mounted on the first substrate 10. Also, a transducer 15 above the auditory aperture 102 is mounted on the first substrate 10. A through cavity 110 formed in the conductive plate 11 not only provides room for different acoustic pressures but also receives the semiconductor chip 14 and the transducer 15.

The conventional condenser microphone provides a protective space defined by the first substrate 10, the through cavity 110 of the conductive plate 11, and the second substrate 12, so as to insulate the semiconductor chip 14 and the transducer 15 and achieve the shielding effect. However, the conductive adhesive layer 13 and the conductive plate 11 differ from each other in constituents, thus deteriorating the shielding effect of the side surface of the condenser microphone. Accordingly, a need is felt of overcoming the aforesaid drawbacks.

### BRIEF SUMMARY

The present disclosure is directed to a lid, the fabricating method thereof, and a MEMS package made thereby with a view to boosting the shielding effect upon the MEMS device.

According to some embodiments of the present disclosure, there are provided a lid for use in a MEMS device and a relative manufacturing method, as defined in claims 1 and 12, respectively.

For instance, in one embodiment the lid comprises: a first board with opposite first and second surfaces, the first surface having a first metal layer disposed thereon, wherein a through cavity extends through the first board and the first metal layer; a second board with opposite third and fourth surfaces; an adhesive layer sandwiched between the second surface of the first board and the third surface of the second board to couple the first and second boards together such that the through cavity is unilaterally blocked by the third surface of the second board so as to form a recess from the through cavity; and a first conductor layer disposed on a bottom surface and a side surface of the recess, the side surface being adjacent to the bottom surface.

Furthermore, one embodiment for fabricating a lid for a MEMS device, comprises the steps of: providing a first board with a first surface having an initial metal layer thereon and an opposite second surface; roughening the initial metal layer of the first board so as to form a first metal layer from the initial metal layer; forming an adhesive layer on the second surface of the first board; forming a through cavity to penetrate the first metal layer, the first board, and the adhesive layer; providing a second board with opposite third and fourth surfaces, and coupling the third surface of the second board and the adhesive layer together thereby covering the through cavity unilaterally to form a recess from the through cavity, wherein the recess has a bottom surface and a side surface adjacent thereto; forming a first conductor layer on the bottom surface and side surface of the recess and the first metal layer.

As disclosed in the present description, in one or more embodiments the shielding effect of the lid is enhanced, not only because the recess is formed by coupling two boards—the first board and the second board—of the same material, but also because the inside of the recess is readily covered by a same layer or stack of layers, such as the first conductor layer.

### BRIEF DESCRIPTION OF THE SEVERAL VIEWS OF THE DRAWINGS

FIG. 1 is a cross-sectional view of a conventional condenser microphone;

FIGS. 2A through 2L are cross-sectional views of an embodiment of a lid for use in a MEMS device, in subsequent manufacture steps;

FIG. 3 shows a simplified block diagram of a capacitive acoustic transducer obtained from the package of FIG. 2L; and

FIG. 4 shows a simplified block diagram of an electronic device including an acoustic transducer.

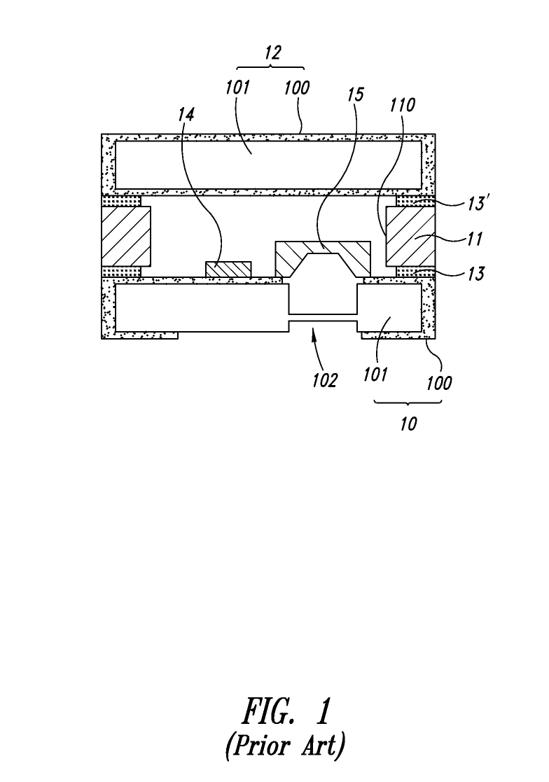

### DETAILED DESCRIPTION

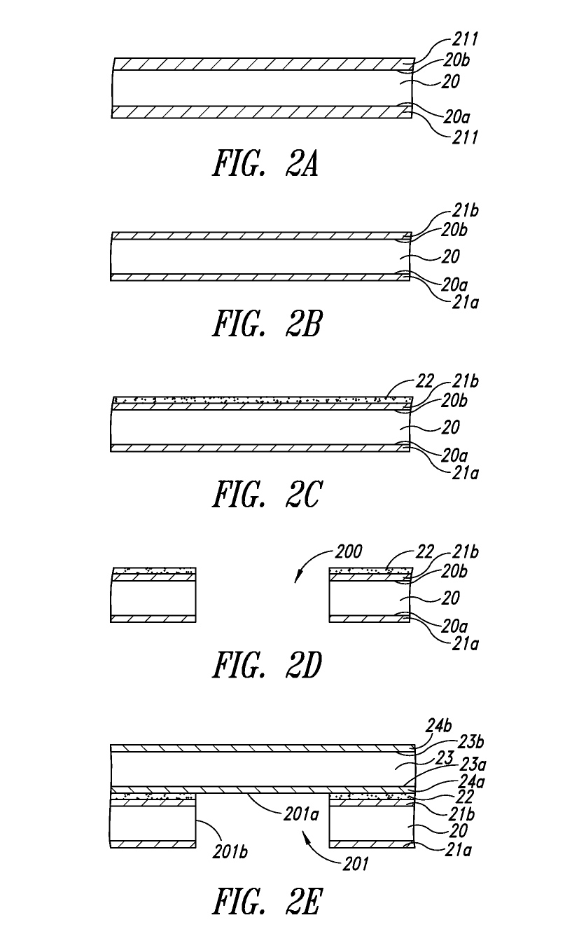

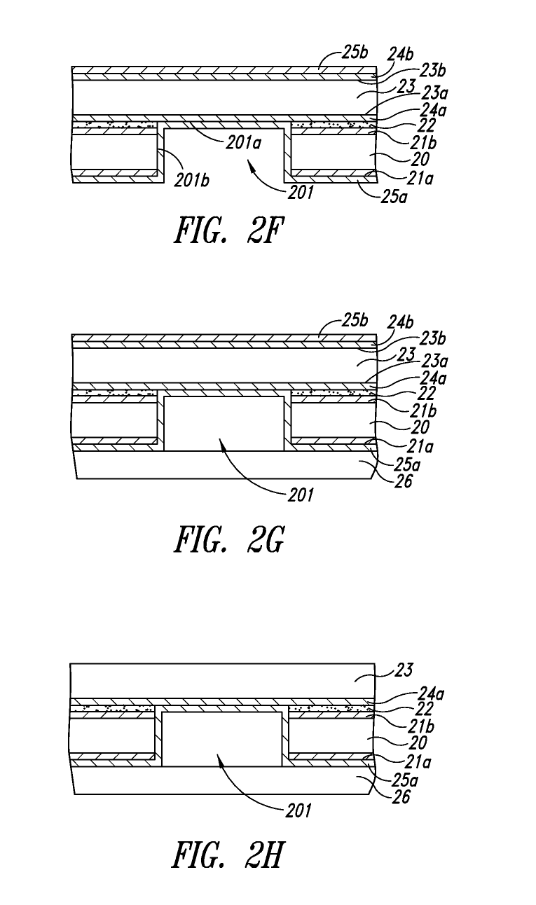

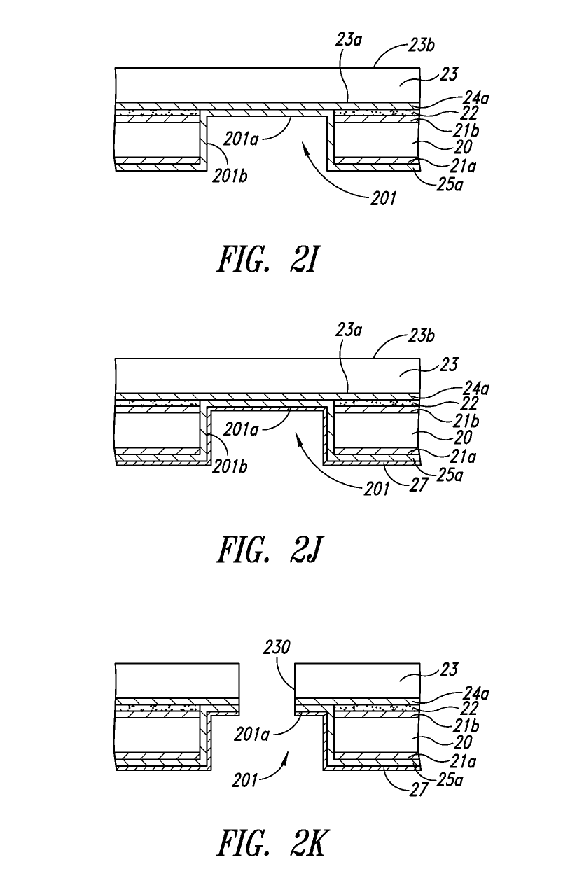

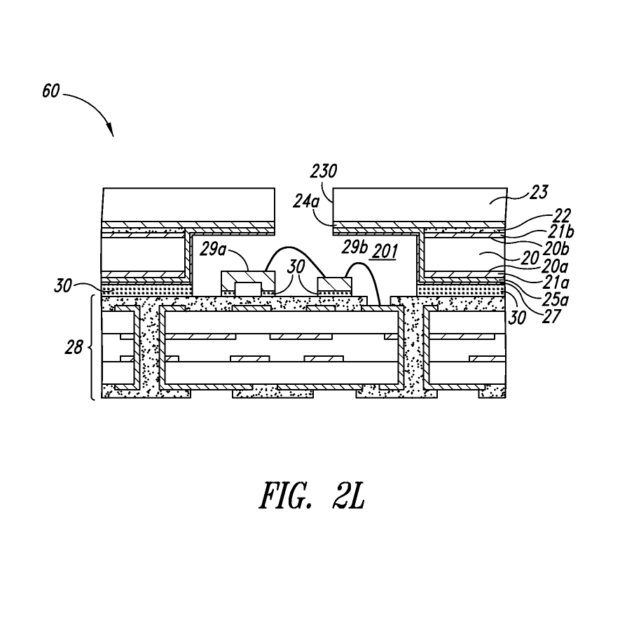

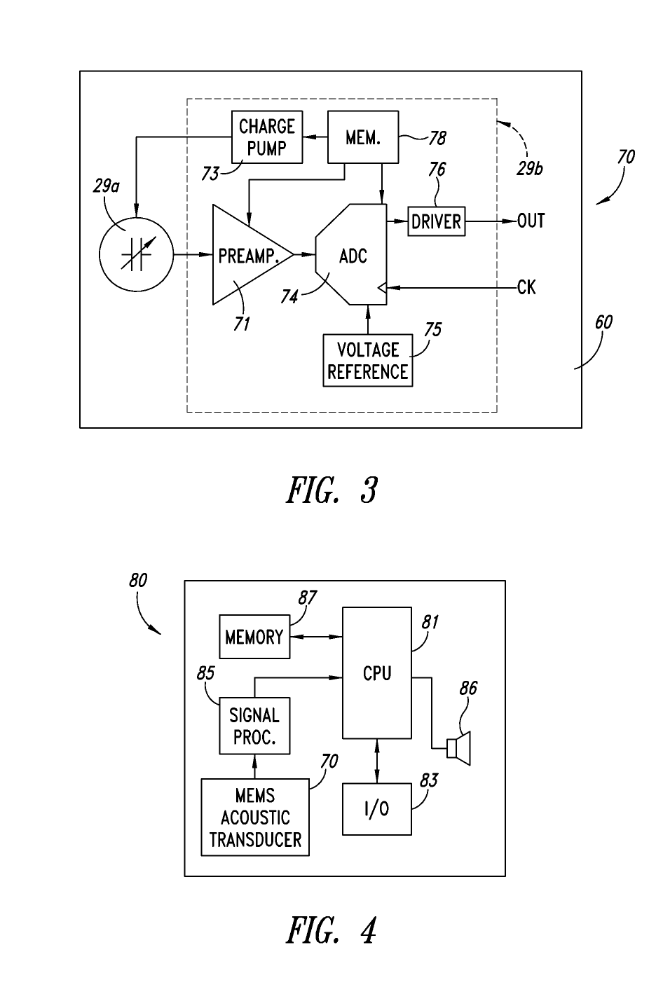

Referring to FIG. 2A, a first board 20 with opposite, first and second, surfaces 20a, 20b is provided. Two initial metal layers 211 are formed on the first and second surfaces 20a, 20b. The initial metal layer 211 is, however, formed on the second surface 20b of the first board 20 on an optional basis.

Referring to FIG. 2B, the initial metal layers 211 on the first and second surfaces 20a, 20b are roughened and thinned by an etching process, so as to form a first metal layer 21a from the initial metal layer 211 on the first surface 20a and form a second metal layer 21b, as a further metal layer, from the initial metal layer 211 on the second surface 20b.

Referring to FIGS. 2C and 2D, an adhesive layer 22 which is a non-conductive layer is formed on the second metal layer 21b as shown in FIG. 2C, and then a through cavity 200 is formed throughout the first metal layer 21a, the first board 20, the second metal layer 21b, and the adhesive layer 22 as shown in FIG. 2D. Referring to FIG. 2E, a second board 23 with opposite third and fourth surfaces 23a, 23b is provided. The third and fourth surfaces 23a, 23b have third and fourth metal layers 24a, 24b formed thereon, respectively, on an optional basis. The third metal layer 24a, as an intermediate metal layer, is coupled to the adhesive layer 22 such that the through cavity 200 is closed on the bottom by the second board 23, thereby forming a recess 201. The recess 201 thus formed has a bottom surface 201a and a side surface 201b adjacent thereto. In one embodiment, the first board 20 and the second board 23 are made of same material, such as BT (Bismaleimide-triazine) core materials or plastics.

Referring to FIG. 2F, a first conductor layer 25a is formed, such as by an electroplating process or a sputtering process, to coat the bottom surface 201a, the side surface 201b of the recess 201, and the first metal layer 21a, and a second conductor layer 25b is formed on the fourth metal layer 24b. The thickness of the first conductor layer 25a is preferably greater than 10 μm. A seed layer (not shown) is formed prior to the formation of the first and second conductor layers 25a, 25b which are made of metal, such as copper. The seed layer functions as an electrical conduction path for electroplating metal and comprises metal, alloy, and a plurality of deposited metal layers.

Referring to FIGS. 2G and 2H, a resist layer 26 is formed above the first conductor layer 25a and the recess 201, as shown in FIG. 2G, and then the second conductor layer 25b and the fourth metal layer 24b are removed as shown in FIG. 2H.

Referring to FIGS. 2I and 2J, the resist layer 26 is removed as shown in FIG. 2I, and then a surface treatment layer 27 comprising nickel, palladium, gold, tin, stainless steel, or a combination thereof is formed on the first conductor layer 25a as shown in FIG. 2J.

As described in the present disclosure, in some embodiments the shielding effect of the lid is enhanced, not only because the recess 201 is formed by coupling two boards, the first board 20 and the second board 23, of the same material, but also because the inside of the recess 201 is readily covered with the same material, such as the first conductor layer 25a.

Referring to FIG. 2K, a hole 230 is formed to penetrate the second board 23, the third metal layer 24a, the bottom surface 201a of the recess 201, the first conductor layer 25a, and the surface treatment layer 27. Thus, a lid 50 for a MEMS device is obtained, comprising the first board 20, the second board 23, the adhesive layer 22, and the first conductor layer 25a. The second board 23 optionally has the third metal layer 24a disposed thereon. The adhesive layer 22 is disposed on the second metal layer 21b so as to be coupled to the third metal layer 24a on the second board 23, or to be coupled directly to the second board 23 without the third metal layer 24a.

Referring to FIG. 2L, in an ensuing process, the lid 50 is applied to a carrier board 28, such as a circuit board, so as to form a package 60. The package 60 accommodates a semiconductor component 29, e.g., an MEMS chip 29a and/or an ASIC chip 29b, mounted on the carrier board 28, thereby forming an MEMS device, such as a microphone, a pressure sensor, or a flux sensor. The carrier board 28 is coupled to the first conductor layer 25a on the first surface 20a of the first board 20 via a conductive coupling layer 30, to achieve grounding and ensure EMI (Electromagnetic Interference) shielding. The semiconductor component 29 is received in the recess 201.

In the embodiment as a microphone, hole 230 forms an acoustic port allowing entrance of sound waves. In other embodiments, hole 230 forms a port allowing entrance of a pressure wave or other quantity to be measured.

The use of BT-core material for both the first and second boards 20, 23 allows the use of production methods similar to those used in the manufacture of BGA (Ball Grid Array) substrate. This results in easy, reliable and cheap manufacture of the parts, using already installed technology and equipment, as well as allows employment of mass production techniques to further reduce costs. In addition, it is easier to adapt the design to different internal and external sizes without expensive tooling costs both at the supplier side and at the packaging stage. In particular, it is possible to have different recess sizes according to silicon properties of the component 29, to have the right combination for optimal frequency response and SNR (Signal-to-Noise Ratio).

It is to be appreciated that the steps of the illustrated method may be performed sequentially, in parallel, omitted, or in an order different from the order that is illustrated.

FIG. 3 shows an acoustic transducer 70 forming a MEMS microphone housed in the package 60.

The acoustic transducer 70 comprises the MEMS chip 29a and the ASIC chip 29b. The MEMS chip 29a is basically constituted by a MEMS sensor responsive to acoustic stimuli, the ASIC chip 29b is configured for correctly biasing the MEMS chip 29a, for processing the generated capacitive variation signal and providing, on an output OUT of the acoustic transducer 70, a digital signal, which can subsequently be processed by a microcontroller of an associated electronic device.

The ASIC chip 29b includes: a preamplifier circuit 71, of an analog type, which is designed to interface directly with the MEMS chip 29a and has a preamplifier function for amplifying (and appropriately filtering) the capacitive variation signal generated by the MEMS chip 29a; a charge pump 73, which enables generation of an appropriate voltage for biasing the MEMS chip 29a; an analog-to-digital converter 74, for example of the sigma-delta type, configured for receiving a clock signal CK and a differential signal amplified by the preamplifier circuit 71 and converting it into a digital signal; a reference-signal generator circuit 75, connected to the analog-to-digital converter 74 and designed to supply a reference signal for the analog-to-digital conversion; and a driver 76, designed to operate as an interface between the analog-to-digital converter 74 and an external system, for example a microcontroller of an associated electronic device.

In addition, the acoustic transducer 70 may comprise a memory 78 (of a volatile or non-volatile type), for example externally programmable so as to enable use of the acoustic transducer 70 according to different configurations (for example, gain configurations).

The acoustic transducer 70 may be used in an electronic device 80, as shown in FIG. 4. The electronic device 80 is for example a mobile-communication portable device, such as a mobile phone, a personal digital assistant (PDA), a notebook, but may be also a voice recorder, a reader of audio files with voice-recording capacity, etc.

Alternatively, the electronic device 80 can be a hydrophone capable of operating under water, or a hearing-aid device.

The electronic device 80 comprises a microprocessor 81 and an input/output interface 83, for example provided with a keyboard and a display, connected to the microprocessor 81. The acoustic transducer 70 communicates with the microprocessor 81 via a signal-processing block 85 (which can carry out further processing operations of the digital signal at output from the acoustic transducer 70). In addition, the electronic device 80 can comprise a loudspeaker 86, for generating sounds on an audio output (not shown), and an internal memory 87.

Finally, it is clear that numerous variations and modifications may be made to the lid, the manufacturing method and the MEMS device. The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

1. A lid for use in a MEMS device, the lid comprising:
a first board having opposite, first and second surfaces, the first surface having a first metal layer disposed thereon, the first board having a recess that extends through the first board and the first metal layer and has side surfaces;
a second board having opposite, third and fourth surfaces;
an adhesive layer located between the second surface of the first board and the third surface of the second board and configured to couple the first board and the second board together, the third surface of the second board at least partially covering the recess and forming a bottom surface of the recess; and
a conductor layer disposed on the bottom surface and the side surfaces of the recess.

2. The lid of claim 1, further comprising an intermediate metal layer disposed on the third surface of the second board, wherein the adhesive layer couples the second surface of the first board with the third surface of the second board via the intermediate metal layer.

3. The lid of claim 1, further comprising an intermediate metal layer disposed on the second surface of the first board, wherein the adhesive layer couples the second surface of the first board with the third surface of the second board via the intermediate metal layer.

4. The lid of claim 1, wherein the conductor layer extends on the first surface of the first board beyond the recess.

5. The lid of claim 1, further comprising a surface treatment layer disposed on the conductor layer.

6. The lid of claim 5, wherein the surface treatment layer is comprises at least one of nickel, palladium, gold, tin, stainless steel, and a combination thereof.

7. The lid of claim 1, further comprising a hole extending through the second board and the conductor layer.

8. The lid of claim 1, wherein the first board and the second board comprise the same material.

9. A MEMS package, comprising:
a lid having:
a first board having opposite, first and second surfaces, the first surface having a first metal layer disposed thereon, the first board having a recess that extends through the first board and the first metal layer and has side surfaces;
a second board having opposite, third and fourth surfaces;
an adhesive layer located between the second surface of the first board and the third surface of the second board and configured to couple the first board and the second board together, the third surface of the second board forming a bottom surface of the recess; and
a conductor layer disposed on the bottom surface and the side surfaces of the recess;
a conductive coupling layer;
a carrier board; and
at least one semiconductor component mounted on the carrier board, wherein the carrier board is coupled to the conductor layer on the first surface of the first board via the conductive coupling layer, and the semiconductor component is located in the recess of the lid.

10. The MEMS package of claim 9, wherein the first and second boards include the same material.

11. An electronic device comprising:
an input/output interface;
a loudspeaker;
a microprocessor control unit coupled to the input/output interface;
an acoustic transducer coupled to the microprocessor control unit, the acoustic transducer including:
a MEMS package including:
a lid having:
a first board having opposite, first and second surfaces, the first surface having a first metal layer disposed thereon, the first board having a recess that extends through the first board and the first metal layer and forms side surfaces;
a second board having opposite, third and fourth surfaces;
an adhesive layer located between the second surface of the first board and the third surface of the second board and configured to couple the first board and the second board together and at least partially cover the recess, the third surface of the second board forming a bottom surface of the recess; and
a conductor layer disposed on the bottom surface and the side surfaces of the recess;
a carrier board; and
at least one semiconductor component, mounted on the carrier board, the carrier board coupled to the first conductor layer on the first surface of the first board via a conductive coupling layer, and the semiconductor component located in the recess of the lid.

12. A method comprising:
fabricating a lid for use in a MEMS device, the fabricating including:
forming a first metal layer on a first surface of a first board;
forming an adhesive layer on a second, opposite surface of the first board;
forming a through cavity extending through the first metal layer, the first board, and the adhesive layer;
coupling a first surface of a second board to the adhesive layer and at least partially closing the through cavity, the first surface of the second board defining a bottom surface of a recess, the through cavity extending through the first board defining side surfaces of the recess;
forming a conductor layer on the bottom surface and the side surfaces of the recess.

13. The method of claim 12, wherein prior to forming an adhesive layer on the first surface of the first board, the method includes:
forming a first metal layer on the first surface of the first board;
forming a second metal layer on a second, opposite surface of the first board; and
roughening the first and second metal layers, wherein forming the adhesive layer comprises forming the adhesive layer on the first metal layer.

14. The method of claim 13, wherein roughening the first and second metal layers includes etching the first and second metal layers.

15. The method of claim 12, wherein forming a conductor layer comprises forming a conductor layer by a sputtering or electroplating process.

16. The method of claim 12, wherein the conductor layer is a first conductor layer, the method further comprising:
forming a metal layer on a second, opposite surface of the second board,
forming a second conductor layer on the metal layer while forming the first conductor layer; and
removing the second conductor layer and the metal layer from the second surface of the second board.

17. The method of claim 12, further comprising forming a hole through the second board and the bottom surface of the recess.

18. The method of claim 12, further comprising forming a surface treatment layer on the conductor layer.

19. The method of claim 18, wherein the surface treatment layer comprises one of nickel, palladium, gold, tin, stainless steel, and a combination thereof

20. The method of claim 12, wherein the first and second boards comprise bismaleimide-triazine or a plastic material.
